(19) United States
(12) Patent Application Publication
(10) Pub. No.: US 2024/0395991 A1
(43) Pub. Date: Nov. 28, 2024

(54) ELECTRONIC DEVICE AND TILED ELECTRONIC DEVICE

(71) Applicant: Innolux Corporation, Miaoli County (TW)

(72) Inventors: Kuang-Pin Chao, Miaoli County (TW); Min-Han Tsai, Miaoli County (TW); Hao-Jung Huang, Miaoli County (TW)

(73) Assignee: Innolux Corporation, Miaoli County (TW)

(21) Appl. No.: 18/644,145

(22) Filed: Apr. 24, 2024

Related U.S. Application Data
(60) Provisional application No. 63/468,267, filed on May 23, 2023.

(30) Foreign Application Priority Data
Feb. 6, 2024 (CN) 202410170740.3

(51) Int. Cl. H01L 33/62; H01L 25/075; H01L 25/16

(52) U.S. Cl. CPC H01L 33/62; H01L 25/0753; H01L 25/167

(57) ABSTRACT

The disclosure provides an electronic device and a tiled electronic device. The electronic device includes a hybrid substrate. The hybrid substrate includes a first circuit substrate, multiple second circuit substrates, an interlayer, and multiple electrical connection units. The first circuit substrate has a first surface and a second surface. The multiple second circuit substrates are disposed on the first surface. The interlayer is disposed between the multiple second circuit substrates and the first circuit substrate. The multiple electrical connection units penetrate the multiple second circuit substrates respectively. At least one electrical connection unit among the plurality of electrical connection units includes a through hole and a conductive material disposed in the through hole. At least one electrical connection unit is electrically connected to the first circuit substrate. The electronic device and the tiled electronic device according to the disclosure can improve process yield or save costs.

### CROSS-REFERENCE TO RELATED APPLICATION

This application claims the priority benefits of U.S. provisional application Ser. No. 63/468,267, filed on May 23, 2023, and China application serial no. 202410170740.3, filed on Feb. 6, 2024. The entirety of each of the above-mentioned patent applications is hereby incorporated by reference herein and made a part of this specification.

### BACKGROUND

### Technical Field

The disclosure relates to an electronic device and a tiled electronic device, and in particular to an electronic device and a tiled electronic device which can improve process yield or save costs.

### Description of Related Art

Electronic devices or tiled electronic devices have been widely used in different fields such as communication, display, automotive, or aviation. With the booming development of electronic devices, electronic devices are developed toward thin and light trends, so the reliability or quality requirements for electronic devices are high.

### SUMMARY

The disclosure provides an electronic device and a tiled electronic device, which can improve process yield or save costs.

According to an embodiment of the disclosure, the electronic device includes a hybrid substrate. The hybrid substrate includes a first circuit substrate, multiple second circuit substrates, an interlayer, and multiple electrical connection units. The first circuit substrate has a first surface and a second surface. The multiple second circuit substrates are disposed on the first surface. The interlayer is disposed between the multiple second circuit substrates and the first circuit substrate. The multiple electrical connection units penetrate the multiple second circuit substrates respectively. At least one electrical connection unit among the plurality of electrical connection units includes a through hole and a conductive material disposed in the through hole. At least one electrical connection unit is electrically connected to the first circuit substrate.

According to an embodiment of the disclosure, the tiled electronic device includes multiple electronic devices. The multiple electronic devices are tiled together with each other. At least one electronic device among the plurality of electronic devices includes a hybrid substrate. The hybrid substrate includes a first circuit substrate, multiple second circuit substrates, an interlayer, and multiple electrical connection units. The first circuit substrate has a first surface and a second surface. The multiple second circuit substrates are disposed on the first surface. The interlayer is disposed between the multiple second circuit substrates and the first circuit substrate. The multiple electrical connection units penetrate the multiple second circuit substrates respectively. At least one electrical connection unit among the plurality of electrical connection units includes a through hole and a conductive material disposed in the through hole. At least one electrical connection unit is electrically connected to the first circuit substrate.

### BRIEF DESCRIPTION OF THE DRAWINGS

The accompanying drawings are included to provide a further understanding of the disclosure, and are incorporated in and form a part of this specification. The drawings illustrate some embodiments of the disclosure and, together with the description, serve to explain the principles of the disclosure.

FIG. 1 is a schematic cross-sectional diagram of an electronic device according to the first embodiment of the disclosure.

FIG. 2 is a schematic cross-sectional diagram of an electronic device according to the second embodiment of the disclosure.

FIG. 3 is a schematic cross-sectional diagram of an electronic device according to the third embodiment of the disclosure.

FIG. 4 is a schematic cross-sectional diagram of an electronic device according to the fourth embodiment of the disclosure.

FIG. 5 is a schematic cross-sectional diagram of a tiled electronic device according to the fifth embodiment of the disclosure.

FIG. 6 is a schematic cross-sectional diagram of a tiled electronic device according to the fifth embodiment of the disclosure.

FIG. 7 is a schematic cross-sectional diagram of a tiled electronic device according to the fifth embodiment of the disclosure.

### DESCRIPTION OF THE EMBODIMENTS

The disclosure may be understood by referring to the following detailed description and combined with the accompanying drawings. It should be noted that, in order to make it easy for readers to understand and for the simplicity of the drawings, some drawings in the disclosure merely depict a part of the electronic device, and certain elements in the drawings are not drawn to actual scale. In addition, the quantity and size of each element in the drawings are merely for illustration and are not used to limit the scope of the disclosure.

In the following description and claims, the words “including” and “comprising” are open-ended words, and thus should be interpreted to mean “including but not limited to . . . ”.

It should be understood that when an element or layer is said to be “on” or “connected to” another element or layer, the element may be directly on the other element or layer or directly connected to the other element or layer, or there is an intervening element or layer between the two elements (in an indirect case). Conversely, when an element is referred to as being “directly on” or “directly connected to” another element or layer, there are no intervening elements or layers present.

Although the terms “first”, “second”, “third” . . . may be used to describe various components or elements, the components or elements are not limited to the terms. The terms are merely used to distinguish a single component element from other component elements in the specification. The same terms may not be used in the claims, but replaced by first, second, third . . . according to the order in which the elements are claimed in the claims. Therefore, in the following description, a first component element may be a second component element in the claims.

In this document, the terms “about”, “approximately”, “substantially”, and “roughly” usually mean within 10%, or within 5%, or within 3%, or within 2%, or within 1%, or within 0.5% of a given value or range. The quantities given here are approximate quantities, that is, without specifically stating “about”, “approximately”, “substantially”, and “roughly”, the meaning of “about”, “approximately”, “substantially”, and “roughly” may still be implied.

In some embodiments of the disclosure, terms related to joining and connecting, such as “connection”, “interconnection”, unless otherwise defined, the terms may mean that two structures are in direct contact, or may also mean that two structures are not in direct contact, in which there are other structures between the two structures. And the terms related to joining and connecting may also include the situation where both structures are movable, or both structures are fixed. In addition, the term “coupling” includes any direct and indirect means of electrical connection.

In some embodiments of the disclosure, optical microscopy (OM), scanning electron microscope (SEM), film thickness profilometer (α-step), ellipse thickness gauge, or other suitable methods may be used to measure the area, width, thickness, or height of each element, or the distance or pitch between elements. Specifically, according to some embodiments, a scanning electron microscope may be used to obtain a cross-sectional structure image containing the elements to be measured, and then the area, width, thickness, or height of each element, or the distance or pitch between elements may be measured.

The electronic device disclosed in the disclosure may include display device, light-emitting device, backlight device, virtual reality device, augmented reality device, antenna device, communication device, sensing device or splicing device, but is not limited thereto. The electronic device may be a bendable or flexible electronic device. The electronic device may include, for example, liquid crystal, light emitting diode, fluorescence, phosphor, other suitable display media, or a combination of the above, but is not limited thereto. The display device may be a non-self-illuminating display device or a self-illuminating display device. The antenna device may be a liquid crystal antenna device or an antenna device of varactor diodes, and the sensing device may be a sensing device sensing capacitance, light, heat, or ultrasonic waves, but is not limited thereto. Electronic devices may include, for example, electronic components such as passive elements and active elements, such as capacitors, resistors, inductors, diodes, and transistors. Diodes may include light emitting diodes or photodiodes. The light emitting diode may include, for example, organic light emitting diode (OLED), mini LED, micro LED, or quantum dot (QD, for example, QLED and QDLED), or other suitable materials, and the materials may be arranged and combined in any way, but are not limited thereto. The antenna device may be, for example, a phase array antenna, but is not limited thereto. The splicing device may be, for example, a display splicing device or an antenna splicing device, but is not limited thereto. It should be noted that the electronic device may be any arrangement and combination mentioned above, but is not limited thereto. In addition, the shape of the electronic device may be a rectangle, a circle, a polygon, a shape with curved edges, or other suitable shapes. The electronic devices may have peripheral systems such as driver systems, control systems, and light source systems to support display devices, antenna devices, wearable devices (for example, including augmented reality or virtual reality), vehicle-mounted devices (for example, including car windshields), or splicing device. The content of the disclosure will be described below with reference to electronic device, but the disclosure is not limited thereto.

It should be noted that, in the following embodiments, features from several different embodiments may be replaced, recombined, and mixed without departing from the spirit of the disclosure to complete other embodiments. Features between various embodiments may be mixed and matched as long as the spirit of the disclosure is not violated and as long as there is no conflict.

Reference will now be made in detail to exemplary embodiments of the disclosure, examples of the embodiments are illustrated in the accompanying drawings. Whenever possible, the same reference numerals are used in the drawings and descriptions to represent the same or similar parts.

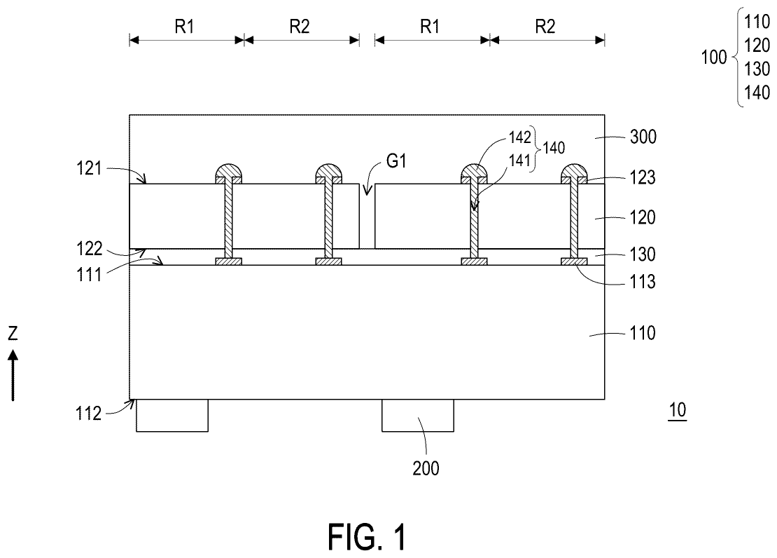

FIG. 1 is a schematic cross-sectional diagram of an electronic device according to the first embodiment of the disclosure. Referring to FIG. 1, an electronic device 10 of this embodiment includes a hybrid substrate 100, a plurality of driver circuits 200, and a molding layer 300. The hybrid substrate 100 includes a first circuit substrate 110, a plurality of second circuit substrates 120, an interlayer 130, and a plurality of electrical connection units 140.

Specifically, the first circuit substrate 110 has a first surface 111 and a second surface 112 opposite to each other. The first circuit substrate 110 at least includes a first circuit layer and a plurality of first pads 113. The first circuit layer may be disposed in the first circuit substrate 110, on the first surface 111, and/or on the second surface 112. The plurality of first pads 113 are respectively disposed on the first surface 111. In this embodiment, the first circuit substrate 110 may be a printed circuit board (PCB), but is not limited thereto. In this embodiment, the first circuit substrate 110 may be a hard substrate, a soft substrate, or a combination of the above. For example, the material of the first circuit substrate 110 may include glass, metal, quartz, sapphire, ceramic, polycarbonate (PC), polyimide (PI), polyethylene terephthalate (PET), other suitable substrate materials, or a combination of the above, but is not limited thereto. In this embodiment, the first circuit substrate 110 may be a passive substrate or an active substrate. When the first circuit substrate 110 is an active substrate, the first circuit substrate 110 may further include a transistor (not shown). In some embodiments, the transistor of the disclosure may include a semiconductor material, such as amorphous silicon, low temperature poly-silicon (LTPS), metal oxide, or a combination of the above materials, and the disclosure is not limited thereto. The structure of the transistor may include a top gate, a bottom gate, a dual gate or double gate, or a combination of the above structures, and the disclosure is not limited thereto. In some embodiments, different transistors may include the same semiconductor material or different semiconductor materials, but are not limited thereto.

The plurality of second circuit substrates 120 are disposed on the first surface 111 of the first circuit substrate 110, which may reduce the number of layers of the first circuit substrate 110 and/or the complexity of related circuit layouts and related elements on the first circuit substrate 110, thereby the cost is reduced. Furthermore, the size of the second circuit substrate 120 may also be reduced to improve the process yield of the second circuit substrate 120. The plurality of second circuit substrates 120 include at least two second circuit substrates 120. The at least two second circuit substrates 120 are separated from each other, and there is a gap G1 between two adjacent second circuit substrates 120. The gap G1 may expose part of the interlayer 130. In this embodiment, although FIG. 1 schematically shows two second circuit substrates 120 on the first surface 111, the disclosure does not limit the number of second circuit substrates. In some embodiments, the number of second circuit substrates disposed on the first surface of the first circuit substrate may also be 3 or more. In this embodiment, “adjacent” means that, between two identical elements, there are no other identical elements.

The second circuit substrate 120 has multiple regions, such as a first region R1 and a second region R2, but is not limited thereto. The second circuit substrate 120 has a third surface 121 and a fourth surface 122 opposite to each other. The fourth surface 122 faces the first surface 111, and the fourth surface 122 is closer to the first circuit substrate 110 than the third surface 121. The second circuit substrate 120 at least includes a second circuit layer (not shown) and a plurality of second pads 123. The second circuit layer may be disposed in the second circuit substrate 120, on the third surface 121, and/or on the fourth surface 122. The plurality of second pads 123 are respectively disposed on the third surface 121 of the first region R1 and the second region R2. The second pad 123 may overlap the first pad 113 in a normal direction Z of the first circuit substrate 110.

In this embodiment, metal traces in the second pad 123 and the second circuit layer may be fine circuits, in which the fine circuits may effectively reduce the number of first substrate stack layers. Line widths of the metal traces in the second pad 123 and the second circuit layer may be smaller than line widths of metal traces in the first pad 113 and the first circuit layer. The line widths of the metal traces in the second pad 123 and the second circuit layer may be, for example, less than or equal to 30 micrometers (μm), but are not limited thereto.

In this embodiment, an area of the second circuit substrate 120 is different from an area of the first circuit substrate 110, and the area of the second circuit substrate 120 may, for example, be smaller than the area of the first circuit substrate 110, but is not limited thereto.

In this embodiment, the second circuit substrate 120 may be a soft substrate, and the material of the second circuit substrate 120 may include polycarbonate, polyimide, polyethylene terephthalate, other suitable soft substrate materials, or a combination of the above, but is not limited thereto. In some embodiments, the second circuit substrate may also be a hard substrate, and the material of the second circuit substrate may also include glass, metal, quartz, sapphire, ceramics, other suitable hard substrate materials, or a combination of the above, but is not limited thereto. In this embodiment, the second circuit substrate 120 may be a passive substrate or an active substrate. When the second circuit substrate 120 is an active substrate, the second circuit substrate 120 may further include a transistor (not shown). In some embodiments, the transistor of the disclosure may include a semiconductor material, such as amorphous silicon, low temperature poly-silicon (LTPS), metal oxide, or a combination of the above materials, and the disclosure is not limited thereto. The structure of the transistor may include a top gate, a bottom gate, a dual gate or double gate, or a combination of the above structures, and the disclosure is not limited thereto. In some embodiments, different transistors may include the same semiconductor material or different semiconductor materials, but are not limited thereto.

The interlayer 130 is disposed on the first pad 113, and the interlayer 130 may cover part of the first pad 113 and the first circuit substrate 110. The interlayer 130 is disposed between fourth surfaces 122 of the plurality of second circuit substrates 120 and the first surface 111 of the first circuit substrate 110. The interlayer 130 may combine and insulate the plurality of second circuit substrates 120 and the first circuit substrate 110, so that the plurality of second circuit substrates 120 may be assembled on the first circuit substrate 110 through the interlayer 130. In this embodiment, the material of the interlayer 130 may include an adhesive material with an insulation function, but is not limited thereto.

The plurality of electrical connection units 140 are respectively disposed on the second pad 123 of the first region R1 and the second region R2, and the plurality of electrical connection units 140 may penetrate the plurality of second pads 123, the plurality of second circuit substrates 120, and the interlayer 130 respectively. The electrical connection unit 140 may overlap the first pad 113 in the normal direction Z of the first circuit substrate 110. At least one electrical connection unit 140 among the plurality of electrical connection units 140 may include a through hole 141 and a conductive material 142. The through hole 141 may penetrate the second pad 123, the second circuit substrate 120, and the interlayer 130 to expose part of the first pad 113. The conductive material 142 is disposed in the through hole 141 and on the second pad 123. In this embodiment, the conductive material 142 may contact the second pad 123 and the first pad 113, but is not limited thereto. The material of the conductive material 142 may include tin, nickel, gold, conductive glue, other suitable conductive materials, or a combination of the above, but is not limited thereto. On the other hand, two side walls of the through hole 141 may be regular side walls, that is, may have substantially smooth surfaces, for example, the surfaces are substantially parallel to the direction Z, but the disclosure is not limited thereto. In some embodiments, the two side walls of the through hole 141 may be side walls formed in irregular shapes, although the side walls still generally extend along the direction Z, the side walls have uneven or irregular surfaces. In some embodiments, the through hole 141 has two inclined side walls respectively, that is, each of the two side walls is not parallel to the normal direction of the first circuit substrate 110 (that is, the direction Z).

At least one electrical connection unit 140 may be electrically connected to the second circuit substrate 120 through the second pad 123, and at least one electrical connection unit 140 may be electrically connected to the first circuit substrate 110 through the first pad 113. That is to say, the second circuit substrate 120 may be electrically connected to the first circuit substrate 110 through the second pad 123, the electrical connection unit 140, and the first pad 113. In this embodiment, since the second circuit substrate 120 may be electrically connected to the first circuit substrate 110 through the electrical connection unit 140 penetrating the second circuit substrate 120 and the interlayer 130, a signal transmission distance between the second circuit substrate 120 and the first circuit substrate 110 may be shortened, thereby signal loss can be reduced or the IR drop problem can be relieved.

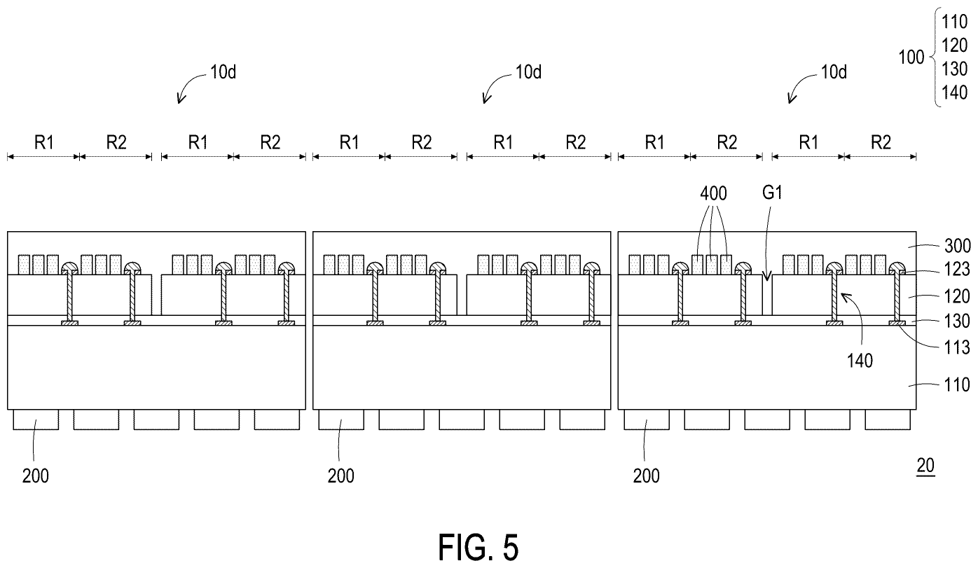

The plurality of driver circuits 200 are disposed on the second surface 112 of the first circuit substrate 110. The driver circuit 200 may be electrically connected to the first circuit layer and the first pad 113 in the first circuit substrate 110, and the driver circuit 200 may be electrically connected to the electrical connection unit 140 through the first circuit layer and the first pad 113 of the first circuit substrate 110. The driver circuit 200 may include a driver IC, a semiconductor-related process structure, or a semiconductor-related process structure disposed on a substrate (such as polyimide, glass, silicon substrate, or other suitable substrate materials), but not limited thereto. In this embodiment, one driver circuit 200 may be disposed corresponding to one first circuit substrate 110. That is to say, a ratio of the number of the driver circuits 200 to the number of the corresponding first circuit substrates 110 may be, for example, 1:1, but not limited thereto. In some embodiments, it may also be that multiple (2 or more) driver circuits are disposed corresponding to one first circuit substrate 110, as shown in FIG. 5. Alternatively, it may be that one driver circuit is disposed corresponding to multiple (2 or more) first circuit substrates 110.

A molding layer 300 is disposed on third surfaces 121 of the plurality of second circuit substrates 120 and in the gap G1. The molding layer 300 may cover the electrical connection unit 140, the second pad 123, and the second circuit substrate 120. In this embodiment, the molding layer 300 may have multiple functions. For example, the molding layer 300 may have a protective function to reduce the probability of the third surface 121 of the second circuit substrate 120 being damaged; and the molding layer 300 may have an optical function to meet optical requirements (such as light absorption or light reflection).

Other embodiments are listed below for illustration. It should be noted here that the following embodiments follow the reference numerals and part of the content of the above embodiments, in which the same reference numerals are used to represent the same or similar elements, and descriptions of the same technical contents are omitted. For descriptions related to the omitted parts, reference may be made to the above embodiments, and details will not be repeated here.

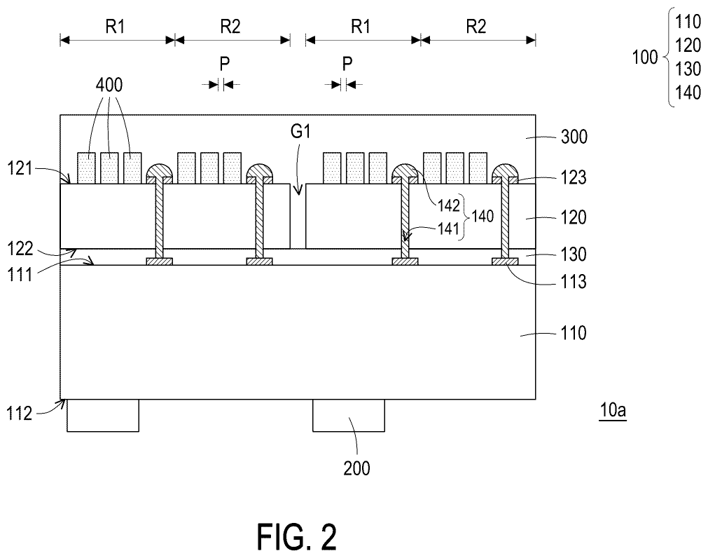

FIG. 2 is a schematic cross-sectional diagram of an electronic device according to the second embodiment of the disclosure. Please refer to FIG. 2 together with FIG. 1. An electronic device 10a of this embodiment is similar to the electronic device 10 of FIG. 1. However, the difference between the electronic device 10a and the electronic device 10 is that, the electronic device 10a of this embodiment further includes a plurality of electronic components 400.

Specifically, please refer to FIG. 2. The plurality of electronic components 400 are respectively disposed on the third surface 121 of the first region R1 and the second region R2 of the multiple second circuit substrates 120. In this embodiment, a pitch P between two adjacent electronic components 400 is a small pitch, and the pitch P may be, for example, less than 1.5 millimeters (mm), but is not limited thereto. The pitch P may be, for example, a minimum distance measured between the two adjacent electronic components 400. In this embodiment, FIG. 2 schematically shows three electronic components 400 in the first region R1 and the second region R2, but the disclosure does not limit the quantity of the electronic components 400.

In this embodiment, the electronic component 400 may be electrically connected to the second circuit layer and the second pad 123 in the second circuit substrate 120, and the electronic component 400 may be electrically connected to the electrical connection unit 140 through the second pad 123 of the second circuit substrate 120. For example, the multiple electronic components 400 located in the first region R1 may be electrically connected to the electrical connection unit 140 located in the first region R1. With this design, the electronic component 400 and the second circuit substrate 120 may be electrically connected through a short distance of the electrical connection unit 140, thereby signal loss can be reduced or the IR drop problem can be relieved.

In this embodiment, the electronic component 400 may include passive elements or active elements, such as capacitors, resistors, inductors, diodes, transistors, but is not limited thereto. The diode may include, for example, a light emitting diode, a photodiode, or a varactor diode, and the light emitting diode may include, for example, an organic light emitting diode, an inorganic light emitting diode, a sub-millimeter light emitting diode, a micro light emitting diode, or a quantum dot light emitting diode, but are not limited thereto.

The molding layer 300 is disposed on the multiple electronic components 400 and in the gap G1. The molding layer 300 may cover the electronic component 400, the electrical connection unit 140, the second pad 123, and the second circuit substrate 120. In this embodiment, the molding layer 300 may have a protective function to reduce the probability of the electronic component 400 being damaged; and the molding layer 300 may also have an optical function to meet optical requirements of the electronic component 400 (such as light absorption or light reflection).

The driver circuit 200 may be used to drive the electronic component 400, and the signal of the driver circuit 200 may be transmitted to the electronic component 400 through a short distance (for example, through the first circuit layer and first pad 113 of the first circuit substrate 110, the electrical connection unit 140, and the second circuit layer and the second pad 123 of the second circuit substrate 120), thereby signal loss can be reduced or the IR drop problem can be relieved. In some embodiments, the driver circuit 200 may include a pixel driver circuit, a scan driver circuit, a data driver circuit, a system driver circuit, a power driver circuit, or other suitable driver circuits, but is not limited thereto.

In a fabrication method of the electronic device 10a in this embodiment, firstly, the driver circuit 200 may be disposed on the first circuit substrate 110 while the electronic component 400 may be disposed on the second circuit substrate 120, and then the second circuit substrate 120 is bonded to the first circuit substrate 110, but is not limited thereto. In some fabrication methods of the electronic device 10a of the embodiment, it may also be that the second circuit substrate 120 is first bonded to the first circuit substrate 110, and then the driver circuit 200 is disposed on the first circuit substrate 110 while the electronic component 400 is disposed on the second circuit substrate 120.

Compared with the design of electronic components generally requiring the use of complex and expensive high-density interconnect (HDI) circuit boards in order to achieve a small pitch (for example, the pitch P is less than 1.5 mm), the electronic device 10 of this embodiment adopts a manner of the hybrid substrate 100 (that is, one first circuit substrate 110 cooperating with multiple second circuit substrates 120), which may not only meet the design of electronic components of small pitch, but also improve the process yield and save costs. For example, in the design of the hybrid substrate 100 (that is, one first circuit substrate 110 cooperating with multiple second circuit substrates 120), when one second circuit substrate 120 among the plurality of second circuit substrates 120 is damaged, the impact is kept limited and does not render the electronic device 10 inoperable entirely, repair may even be performed in a manner of simply replacing the second circuit substrate.

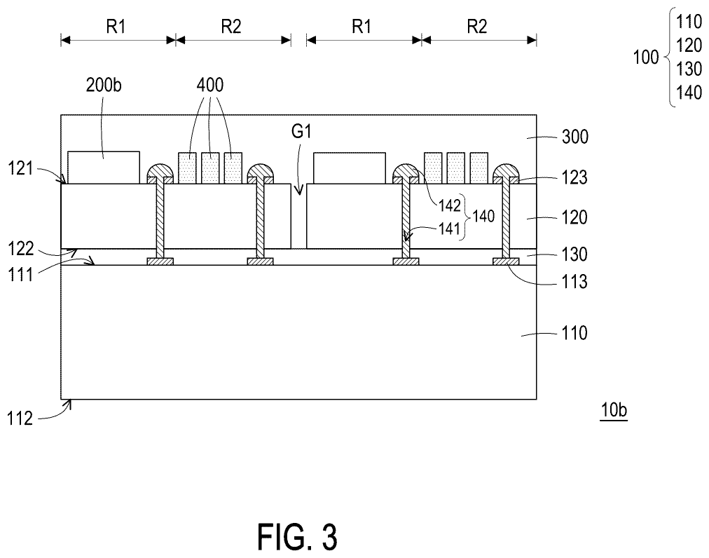

FIG. 3 is a schematic cross-sectional diagram of an electronic device according to the third embodiment of the disclosure. Please refer to FIG. 3 together with FIG. 2. An electronic device 10b of this embodiment is similar to the electronic device 10a of FIG. 2. However, the difference between the electronic device 10b and the electronic device 10a is that, in the electronic device 10b of this embodiment, multiple driver circuits 200b are disposed on the third surfaces 121 of the multiple second circuit substrates 120 and the multiple driver circuits 200b are on the same side as the multiple electronic components 400, which may simplify wire connections between the driver circuit 200b and the electronic component 400. Furthermore, the multiple driver circuits 200b and the multiple electronic components 400 may be separately transferred to the second circuit substrate 120 in the same manner to simplify the process. In some embodiments, the multiple driver circuits 200b and/or the electronic components 400 may be in the form of die without individual packaging in advance, and packaging protection may be performed subsequently by using the forming layer 300, which can simplify the overall structure, and the fabrication cost is reduced.

Specifically, please refer to FIG. 3. The driver circuit 200b is disposed in the first region R1 of the second circuit substrate 120, for example, but is not limited thereto. The driver circuit 200b may be electrically connected to the second circuit substrate 120. In some embodiments, the driver circuit 200b may include a pixel driver circuit, a scan driver circuit, a data driver circuit, a system driver circuit, a power driver circuit, or other suitable driver circuits, but is not limited thereto. Moreover, the electronic component 400 may be electrically connected to the corresponding electrical connection unit 140 through the second pad 123 of the first region R1 of the second circuit substrate 120. In addition, the signal of the driver circuit 200b may be transmitted to the electronic component 400 through a short distance (for example, through the second circuit layer in the first region R1 and the second region R2 of the second circuit substrate 120), thereby signal loss can be reduced or the IR drop problem can be relieved.

The molding layer 300 is disposed on the multiple electronic components 400 and the multiple driver circuits 200b, and the molding layer 300 may also be disposed in the gap G1. The molding layer 300 may cover the electronic component 400, the driver circuit 200b, the electrical connection unit 140, the second pad 123, and the second circuit substrate 120.

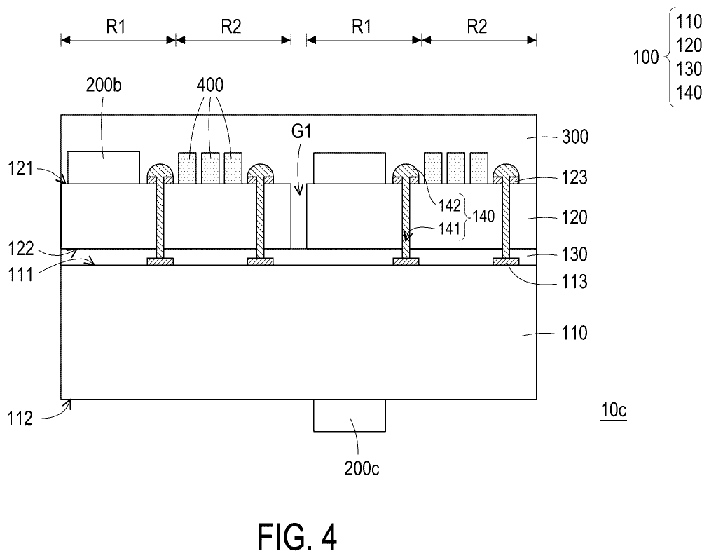

FIG. 4 is a schematic cross-sectional diagram of an electronic device according to the fourth embodiment of the disclosure. Please refer to FIG. 4 together with FIG. 3. An electronic device 10c of this embodiment is similar to the electronic device 10b of FIG. 3. However, the difference between the electronic device 10c and the electronic device 10b is that, the electronic device 10c of this embodiment further includes a driver circuit 200c.

Specifically, please refer to FIG. 4. The driver circuit 200c is disposed on the second surface 112 of the first circuit substrate 110. The driver circuit 200c may drive the electronic component 400 of the first region R1 through the driver circuit 200b located in the first region R1, and the driver circuit 200c may also drive the electronic component 400 of the second region R2 through the driver circuit 200b located in the second region R2.

The signal of the driver circuit 200c may be transmitted to the electronic component 400 through a short distance, (for example, through the electrical connection unit 140 of the first region R1, the driver circuit 200b, and the second circuit layer of the second circuit substrate 120), thereby signal loss can be reduced or the IR drop problem can be relieved. In some embodiments, the driver circuit 200c may include a pixel driver circuit, a scan driver circuit, a data driver circuit, a system driver circuit, a power driver circuit, or other suitable driver circuits, but is not limited thereto.

FIG. 5 is a schematic cross-sectional diagram of a tiled electronic device according to the fifth embodiment of the disclosure. Please refer to FIG. 5 together with FIG. 2. A tiled electronic device 20 of this embodiment is similar to the electronic device 10a of FIG. 2. However, the difference between the tiled electronic device 20 and the electronic device 10a is that, the tiled electronic device 20 of this embodiment includes multiple electronic devices 10d.

Specifically, please refer to FIG. 5. The multiple electronic devices 10d in the tiled electronic device 20 are disposed adjacently and tiled together with each other, in which in the electronic device 10d, each first circuit substrate 110 may correspond to the multiple driver circuits 200.

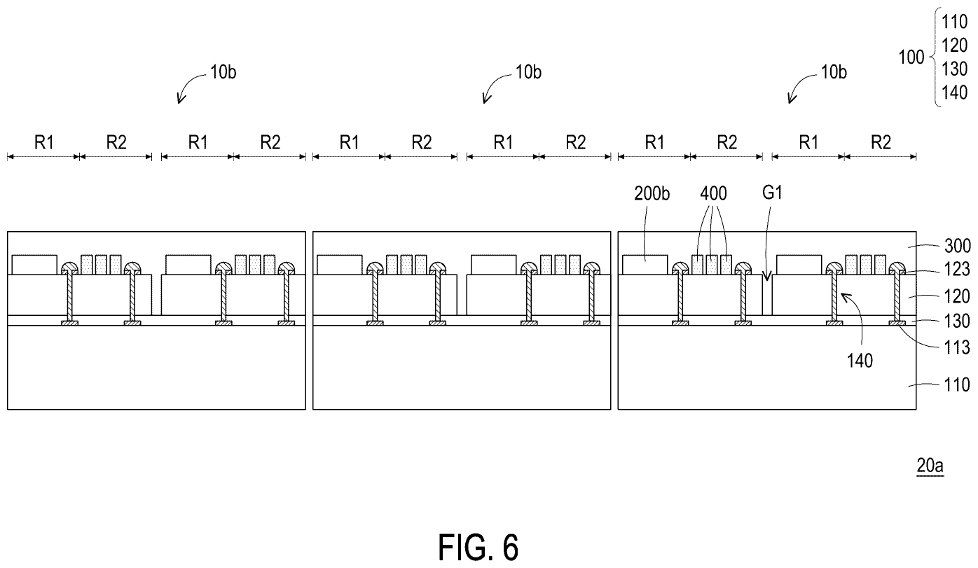

FIG. 6 is a schematic cross-sectional diagram of a tiled electronic device according to the fifth embodiment of the disclosure. Please refer to FIG. 6 together with FIG. 3. A tiled electronic device 20a of this embodiment is similar to the electronic device 10b of FIG. 3. However, the difference between the tiled electronic device 20a and the electronic device 10b is that, the tiled electronic device 20a of this embodiment includes multiple electronic devices 10b. The multiple electronic devices 10b in the tiled electronic device 20a are disposed adjacently and tiled together.

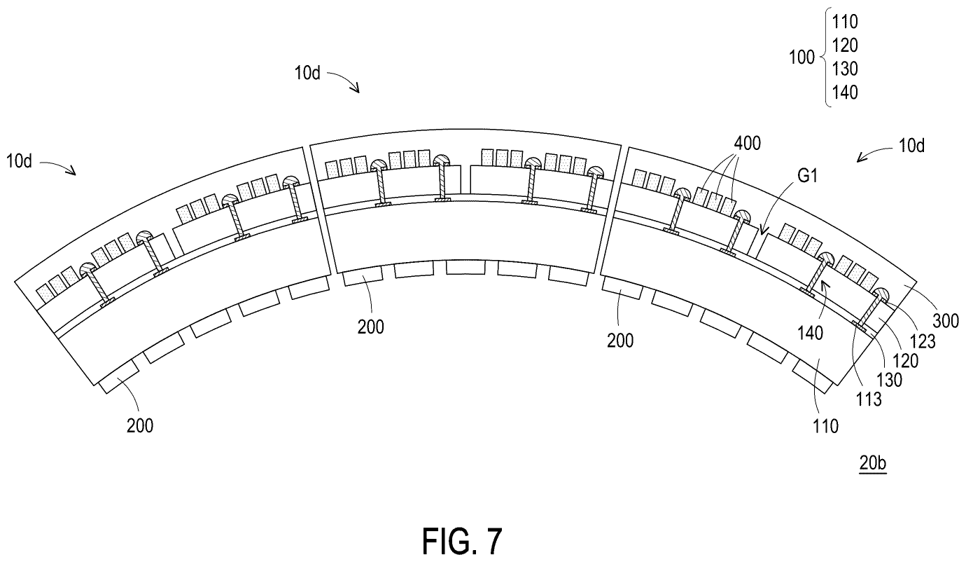

FIG. 7 is a schematic cross-sectional diagram of a tiled electronic device according to the fifth embodiment of the disclosure. Please refer to FIG. 7 together with FIG. 2. The tiled electronic device 20b of this embodiment is similar to the tiled electronic device 20 of FIG. 5. However, the difference between the tiled electronic device 20b and the tiled electronic device 20 is that, the tiled electronic device 20b of this embodiment is bendable and/or a tiled electronic device comprising a curved surface.

Specifically, please refer to FIG. 7. The first circuit substrate 110 and the second circuit substrate 120 are soft substrates, and the materials of the first circuit substrate 110 and the second circuit substrate 120 have flexible characteristics. Thereby, the tiled electronic device 20b may be fixed on a curved surface or a surface having a specific radius curvature to form a bendable tiled electronic device.

In summary, in the electronic device and the tiled electronic device according to the embodiments of the disclosure, a manner of the hybrid substrate method (that is, one first circuit substrate cooperating with multiple second circuit substrates) is adopted, which may not only meet the design of electronic components of small pitch, but also the evenness of the surface of the substrate can also be improved to suit the transfer and electrical connection of electronic components, the size and position precision of the substrate can also be improved to suit the large-volume transfer of electronic components, the process yield can be improved, or the cost is reduced. In addition, since the second circuit substrate may be electrically connected to the first circuit substrate through the electrical connection unit penetrating the second circuit substrate and the interlayer, the signal transmission distance between the second circuit substrate and the first circuit substrate may be shortened, thereby signal loss can be reduced or the IR drop problem can be relieved.

Finally, it should be noted that, the above embodiments are merely used to illustrate the technical solution of the disclosure, but the embodiments are not to limit the disclosure. Although the disclosure has been described in detail with reference to the embodiments, persons of ordinary skill in the art should understand that, persons of ordinary skill in the art may still modify the technical solutions recorded in the embodiments, or make equivalent substitutions for some or all of the technical features. However, the modifications or substitutions do not cause the essence of the corresponding technical solution to deviate from the scope of the technical solution according to embodiments of the disclosure.

What is claimed is:

1. An electronic device, comprising:
a hybrid substrate, wherein the hybrid substrate comprises:
a first circuit substrate, having a first surface and a second surface;
a plurality of second circuit substrates, disposed on the first surface;
an interlayer, disposed between the plurality of second circuit substrates and the first circuit substrate; and
a plurality of electrical connection units, penetrating the plurality of second circuit substrates respectively, wherein at least one electrical connection unit among the plurality of electrical connection units comprises a through hole and a conductive material disposed in the through hole, and the at least one electrical connection unit is electrically connected to the first circuit substrate.

2. The electronic device according to claim 1, wherein the interlayer combines and insulates the plurality of second circuit substrates and the first circuit substrate.

3. The electronic device according to claim 1, further comprising:
a plurality of electronic components and/or a plurality of driver circuits disposed on third surfaces of the plurality of second circuit substrates.

4. The electronic device according to claim 3, further comprising:
a molding layer, disposed on the plurality of electronic components and/or the plurality of driver circuits.

5. The electronic device according to claim 3, wherein a pitch between two adjacent electronic components among the plurality of electronic components is less than 1.5 mm.

6. The electronic device according to claim 3, wherein the plurality of electronic components are electrically connected to the first circuit substrate through the at least one electrical connection unit.

7. The electronic device according to claim 1, further comprising:
a plurality of driver circuits, disposed on the second surface of the first circuit substrate.

8. The electronic device according to claim 7, further comprising:
a plurality of electronic components, disposed on third surfaces of the plurality of second circuit substrates, wherein the plurality of driver circuits are electrically connected to the plurality of electronic components through the at least one electrical connection unit.

9. The electronic device according to claim 1, further comprising:
a molding layer, disposed on the plurality of second circuit substrates.

10. The electronic device according to claim 1, wherein the plurality of second circuit substrates comprise at least two second circuit substrates, and the at least two second circuit substrates are separated from each other.

11. The electronic device according to claim 10, wherein there is a gap between the at least two second circuit substrates, and the gap exposes part of the interlayer.

12. The electronic device according to claim 1, wherein line widths of metal traces in the plurality of second circuit substrates are smaller than line widths of metal traces in the first circuit substrate.

13. The electronic device according to claim 12, wherein the line widths of the metal traces in the plurality of second circuit substrates are less than or equal to 30 micrometers.

14. The electronic device according to claim 1, wherein an area of each of the plurality of second circuit substrates is smaller than an area of the first circuit substrate.

15. The electronic device according to claim 1, wherein the first circuit substrate comprises a first pad disposed on the first surface, the plurality of second circuit substrates comprise second pads disposed on the third surfaces, and the at least one electrical connection unit is electrically connected to the first pad and the second pad.

16. The electronic device according to claim 15, wherein the plurality of second circuit substrates are electrically connected to the first circuit substrate through the second pad, the at least one electrical connection unit, and the first pad.

17. The electronic device according to claim 15, wherein the at least one electrical connection unit overlaps the first pad and the second pad in a normal direction of the first circuit substrate.

18. The electronic device according to claim 15, wherein the plurality of electrical connection units penetrate the second pad, the plurality of second circuit substrates, and the interlayer.

19. The electronic device according to claim 1, wherein the plurality of second circuit substrates have a plurality of regions, and the plurality of electrical connection units are disposed in the plurality of regions.

20. A tiled electronic device, comprising a plurality of electronic devices, wherein the plurality of electronic devices are tiled together with each other, and at least one electronic device among the plurality of electronic devices comprises:
a hybrid substrate, wherein the hybrid substrate comprises:
a first circuit substrate, having a first surface and a second surface;
a plurality of second circuit substrates, disposed on the first surface;
an interlayer, disposed between the plurality of second circuit substrates and the first circuit substrate; and
a plurality of electrical connection units, penetrating the plurality of second circuit substrates respectively, wherein at least one electrical connection unit among the plurality of electrical connection units comprises a through hole and a conductive material disposed in the through hole, and the at least one electrical connection unit is electrically connected to the first circuit substrate.
